(19) United States
(12) Patent Application Publication
(10) Pub. No.: US 2023/0413589 A1
(43) Pub. Date: Dec. 21, 2023

(54) LIGHT-EMITTING ELEMENT

(71) Applicant: SHARP KABUSHIKI KAISHA, Sakai City, Osaka (JP)

(72) Inventors: TAKAYUKI NAKA, Sakai City, Osaka (JP); NOBORU IWATA, Sakai City, Osaka (JP); MAKOTO IZUMI, Sakai City, Osaka (JP)

(21) Appl. No.: 18/031,329

(22) PCT Filed: Oct. 14, 2020
(86) PCT No.: PCT/JP2020/038705

§ 371 Date: Apr. 11, 2023

(51) Int. Cl. H10K 50/115

(52) U.S. Cl. CPC H10K 50/115; H10K 2101/40

(57) ABSTRACT

A light-emitting element includes: an anode; a cathode provided across from the anode; and a light-emitting layer provided between the anode and the cathode, and containing first quantum dots and second quantum dots, the first quantum dots each having a core-shell structure including a first core and a first shell provided on a surface of the first core, and the second quantum dots each having a core-shell structure including a second core and a second shell provided on a surface of the second core. A CBM of the first shell is lower than a CBM of the second shell, and a VBM of the first shell is lower than a VBM of the second shell.

### TECHNICAL FIELD

The present disclosure relates to a light-emitting element.

### BACKGROUND ART

Patent Document 1 discloses, for example, a light-emitting element including a light-emitting layer containing non-light-emitting quantum dots.

### CITATION LIST

### Patent Document

[Patent Document 1] United States Patent Application Publication No. 2019/0280232

### SUMMARY OF INVENTION

### Technical Problem

The light-emitting layer of the light-emitting element described in Patent Document 1 contains non-light-emitting quantum dots, which could impair not only the electron transport capability but also the hole transport capability of the light-emitting layer. Hence, the light-emitting layer might suffer reduction in light emission efficiency such as, for example, luminance and external quantum efficiency (EQE).

The present disclosure is essentially intended to provide a light-emitting element capable of improving light emission efficiency.

### Solution to Problem

A light-emitting element according to an aspect of the present disclosure includes: an anode; a cathode provided across from the anode; and a light-emitting layer provided between the anode and the cathode, and containing first quantum dots and second quantum dots, the first quantum dots each having a core-shell structure including a first core and a first shell provided on a surface of the first core, and the second quantum dots each having a core-shell structure including a second core and a second shell provided on a surface of the second core, wherein a CBM of the first shell is lower than a CBM of the second shell, and a VBM of the first shell is lower than a VBM of the second shell.

A light-emitting element according to an aspect of the present disclosure includes: an anode; a cathode provided across from the anode; and a light-emitting layer provided between the anode and the cathode, and containing first quantum dots and second quantum dots, the first quantum dots each having a core-shell structure including a first core and a first shell provided on a surface of the first core, and the second quantum dots each having a core-shell structure including a second core and a second shell provided on a surface of the second core, wherein the first shell contains at least S or Se, and the second shell contains Te.

### BRIEF DESCRIPTION OF DRAWINGS

FIG. 1 is a schematic view of an exemplary multilayer structure of a light-emitting element according to a first embodiment.

FIG. 2 is an example of a schematic diagram showing an energy level of each of the layers in the light-emitting element according to the first embodiment.

FIG. 3 is a schematic view of an exemplary multilayer structure of the light-emitting element according to a second embodiment.

FIG. 4 is a schematic view of an exemplary multilayer structure of a light-emitting element according to a third embodiment.

### DESCRIPTION OF EMBODIMENTS

Embodiments described below are mere examples of the present disclosure. The present disclosure shall not be limited to the embodiments below.

### First Embodiment

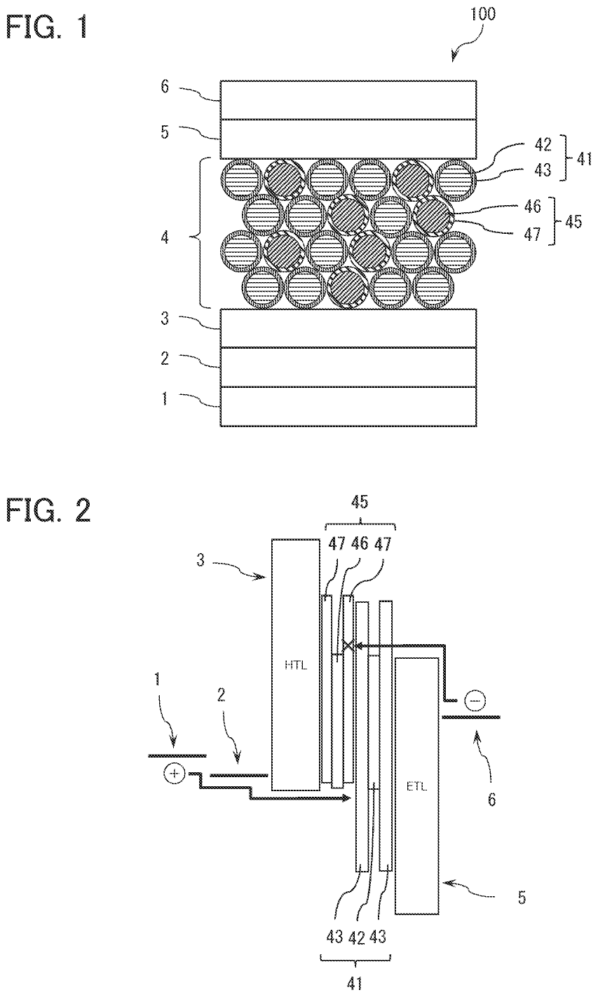

FIG. 1 is a schematic view of an exemplary multilayer structure of a light-emitting element 100 according to this embodiment.

As illustrated in FIG. 1, the light-emitting element 100 includes, for example, an anode 1, a hole injection layer 2, a hole transport layer 3, a light-emitting layer 4, an electron transport layer 5, and a cathode 6, all of which are stacked on top of another in the stated order. Note that a plurality of the light-emitting elements 100 are arranged so that a display device can be formed.

The anode 1 supplies the light-emitting layer 4 with holes.

The cathode 6 supplies the light-emitting layer 4 with electrons. Moreover, the cathode 6 is provided across from the anode 1.

Either the anode 1 or the cathode 6 is made of a light-transparent material. Note that either the anode 1 or the cathode 6 may be made of a light-reflective material. If the light-emitting element 100 is a top-emission light-emitting element, for example, the cathode 6 provided above is formed of a light-transparent material, and the anode 1 provided below is formed of a light-reflective material. If the light-emitting element 100 is a bottom-emission light-emitting element, for example, the cathode 6 provided above is formed of a light-reflective material, and the anode 1 provided below is formed of a light-transparent material. Moreover, either the anode 1 or the cathode 6 may be a multilayer stack made of a light-transparent material and a light-reflective material, so that the electrode can reflect light.

The light-transparent material may be, for example, a transparent conductive material. Specific examples of the light-transparent material may include: indium tin oxide (ITO); indium zinc oxide (IZO); tin oxide (SnO₂); and fluorine-doped tin oxide (FTO). Because these materials are highly transparent to visible light, the light-emitting element 100 improves light emission efficiency.

The light-reflective material may be, for example, a metal material. Specific examples of the light-reflective material may include: aluminum (Al); silver (Ag); copper (Cu); and gold (Au). Because these materials are highly reflective to visible light, the light-emitting element 100 improves light emission efficiency.

Note that the anode 1 and the cathode 6 can be made of a conventionally known technique such as, for example, sputtering or vacuum evaporation. For example, if the anode 1 is formed of ITO, the anode 1 can be formed by sputtering. For example, if the cathode 6 is formed of Al, the cathode 6 can be formed by vacuum evaporation.

The light-emitting layer 4 is provided between the anode 1 and the cathode 6, and emits light. The light-emitting layer 4 contains: a plurality of first quantum dots 41 and a plurality of second quantum dots 45. In this embodiment, the first quantum dots 41 and the second quantum dots 45 are irregularly mixed together and arranged in the light-emitting layer 4.

Note that the light-emitting layer 4 is preferably composed only of the first quantum dots 41 and the second quantum dots 45. Such a feature can further improve light emission efficiency such as, for example, luminance and EQE. Note that the first quantum dots 41 and the second quantum dots 45 will be described in detail later.

Note that each of the quantum dots has a maximum width of 1 nm or more and 100 nm or less. The quantum dots may have any given shape as long as their maximum width is within the above range, and the shape of the quantum dot shall not be limited to a spherical shape (a circular cross-section). For example, the quantum dots may have a polygonal shape in cross-section, a bar-like shape, a branch-like shape, or asperities on the surface. Alternatively, the quantum dots may have a combination of such shapes.

Note that at least the first quantum dots 41 emit light by recombination of the holes transported from the anode 1 and the electrons transported from the cathode 6. Specifically, a voltage or a current is applied between the anode 1 and the cathode 6, and the transported holes and electrons recombine together in the light-emitting layer 5. Hence, the light-emitting layer 5 emits light.

The hole transport layer 3 is provided between the anode 1 and the light-emitting layer 4, and transports the holes, sent from the anode 1, to the light-emitting layer 4. The hole transport layer 3 contains a hole transport material.

The hole transport material can be selected appropriately from materials typically used in this field. Examples of the hole transport materials include an organic hole transport material and an inorganic hole transport material.

Examples of the organic hole transport material include: such a material as 4,4′,4″-tris(9-carbazolyl)triphenylamine (TCTA), 4,4′-bis[N-(1-naphthyl)-N-phenyl-amino]biphenyl (NPB), zinc phthalocyanine (ZnPC), di[4-(N,N-ditolylamino)phenyl]cyclohexane (TAPC), 4,4′-bis(carbazol-9-yl)biphenyl (CBP), 2,3,6,7,10,11-hexacyano-1,4,5,8,9,12-hexaazatriphenylene (HATCN), or (3,4-ethylenedioxythiophene):poly(4-styrene sulfonate) (PEDOT-PSS); poly(N-vinylcarbazole) (PVK); poly(2,7-(9,9-di-n-octylfluorene)-(1,4-phenylene((4-sec-butylphenyl)imino)-1,4-phenylene (TFB); and poly(triphenylamine) derivative (poly-TPD).

Examples of the inorganic hole transport material include, as a metal oxide, for example, a material containing one or more selected from a group consisting of an oxide, a nitride, or a carbide containing any one or more of Zn, Cr, Ni, Ti, Nb, Al, Si, Mg, Ta, Hf, Zr, Y, La, Sr, and Mo.

The hole transport layer 3 preferably contains the above inorganic hole transport material (an inorganic material). Such a feature can further improve reliability of the light-emitting element 100.

The hole transport layer 3 preferably has a thickness of 15 nm or more and 80 nm or less. If the hole transport layer 3 has a thickness of less than 15 nm, the hole transport capability of the hole transport layer 3 could be impaired. Moreover, if the hole transport layer 3 has a thickness of more than 80 nm, a drive voltage of the light-emitting element 100 rises, possibly miniaturizing the current.

Note that, depending on the material in forming, the hole transport layer 3 can be formed, for example, by coating such as spin coating or dip coating, sol-gel process, sputtering, vacuum evaporation, or the CVD.

The hole injection layer 2 is provided between the anode 1 and the hole transport layer 3, and injects the holes, sent from the anode 1, to the hole transport layer 3. The hole injection layer 2 contains a hole transport material similar to the hole transport material of the hole transport layer 3. In conjunction with the materials of the anode 1 and the hole transport layer 3, the hole transport material of the hole injection layer 2 is selected appropriately so that the holes are transported with high efficiency from the anode 1 to the light-emitting layer 4. Note that the hole injection layer 2 and the hole transport layer 3 are preferably made of different materials.

The hole injection layer 2 preferably has a thickness of 10 nm or more and 100 nm or less. If the hole injection layer 2 has a thickness of less than 10 nm, the hole transport capability of the hole injection layer 2 could be impaired. Moreover, if the hole injection layer 2 has a thickness of more than 100 nm, the uniformity in the thickness of the hole injection layer 2 might be impaired. As a result, efficiency could decrease in injecting the holes into the hole transport layer 3.

Note that, depending on the material in forming, the hole injection layer 2 can be formed, for example, by coating such as spin coating or dip coating, sol-gel process, sputtering, vacuum evaporation, or the CVD.

Moreover, in the light-emitting element 100 of this embodiment, the hole transport layer 3 and the hole injection layer 2 are not essential. For example, both the hole transport layer 3 and the hole injection layer 2 may be omitted, and the anode 1 and the light-emitting layer 4 may directly be in contact with each other. Alternatively, the hole injection layer 2 may be omitted, and the anode 1, the hole transport layer 3, and the light-emitting layer 4 may be stacked on top of another.

The electron transport layer 5 is provided between the cathode 6 and the light-emitting layer 4, and transports the electrons, sent from the cathode 6, to the light-emitting layer 4. The electron transport layer 5 contains an electron transport material.

The electron transport material can be selected appropriately from materials typically used in this field. Examples of the electron transport materials include a compound and a complex containing one or more nitrogen-containing hetero rings such as oxadiazole rings, triazole rings, triazine rings, quinoline rings, phenanthroline rings, pyrimidine rings, pyridine rings, imidazole rings, and carbazole rings. Specifically, the examples include: 1,10-phenanthroline derivatives such as bathocuproine and bathophenanthroline; benzimidazole derivatives such as 1,3,5-tris(N-phenylbenzimidazol-2-yl)benzene (TPBI); metal complexes such as a bis(10-benzoquinolinolato)beryllium complex, an 8-hydroxyquinoline aluminum complex, and a bis(2-methyl-8-quinolinato)-4-phenylphenolate aluminum complex; and 4,4′-biscarbazolbiphenyl. Other specific examples include: an aromatic phosphine compound such as an aromatic boron compound, an aromatic silane compound, or phenyldi(1-pyrenyl)phosphine; and a nitrogen-containing hetero ring compound such as bathophenanthroline, bathocuproine, 2,2′,2″-(1,3,5-benzenetriyl)tris(1-phenyl-1H-benzimidazole)(TPBI), or a triazine derivative. Still other specific examples include zinc oxide (ZnO), magnesium zinc oxide (MgZnO), titanium oxide (TiO₂), and strontium oxide (SrTiO₃). These materials may be nanoparticles.

Note that, depending on the material in forming, the electron transport layer 5 can be formed, for example, by coating such as spin coating or dip coating, sol-gel process, sputtering, or the CVD.

Moreover, in the light-emitting element 100 of this embodiment, the electron transport layer 5 is not essential. For example, the electron transport layer 5 may be omitted, and the cathode 6 and the light-emitting layer 4 may directly be in contact with each other.

Described below in detail are the first quantum dots 41 and the second quantum dots 45 of the light-emitting layer 4.

Each of the first quantum dots 41 has a core-shell structure including, for example: a first core 42; and a first shell 43 provided on a surface of the first core 42. As to the above core-shell structure, for example, the shell may at least partially cover the core. Preferably, the shell coats the entire core. The core-shell structure is checked, for example, as follows: When a cross-section of each of 50 neighboring quantum dots is observed, a diameter (an assumed dot diameter) is calculated of a circle corresponding to an area of the cross-section of the quantum dot, and a core diameter (an assumed core diameter) is calculated from an emission peak wavelength. Here, if the difference between the assumed dot diameter and the assumed core diameter is 0.3 nm or more, it can be understood that the shell covers the core (the shell coats the entire core). Note that the cross-section can be observed with a scanning transmission electron microscope (STEM).

Each of the second quantum dots 45 has a core-shell structure including, for example: a second core 46; and a second shell 47 provided on a surface of the second core 46. The core-shell structure of the second quantum dots 45 is the same as that of the first quantum dots 41.

A conduction band minimum (CBM) of the first shell 43 is preferably lower than a CBM of the second shell 47. Moreover, a valence band maximum (VBM) of the first shell 43 is preferably higher than a VBM of the second shell 47. That is, an electron affinity of the first shell 43 is preferably higher than an electron affinity of the second shell 47. Moreover, an ionization potential of the first shell 43 is preferably higher than an ionization potential of the second shell 47.

FIG. 2 is an example of a schematic diagram showing an energy level of each of the layers in the light-emitting element 100. The sign “−” denotes electrons, and the sign “+” denotes holes. If the light-emitting element 100 did not have such a configuration, the carrier balance between the electrons and the holes would be lost, the electrons would be found in excessively large amount, and the excessively large amount of electrons would flow into the hole transport layer. FIG. 2 shows that the configuration of the light-emitting element 100 reduces such problems. That is, the second shells 47 create a high barrier against the electrons, thereby making it possible to reduce the flow of the electrons into the hole transport layer. Moreover, if the light-emitting element 100 did not have such a configuration, the carrier balance between the electrons and the holes would be lost, and the holes would be found in excessively small amount. The configuration of the light-emitting element 100 reduces such problems. That is, the second shells 47 lower a barrier against the holes and the holes can readily move in the light-emitting layer, thereby making it possible to improve the carrier balance.

A VBM of the first core 42 is preferably higher than the VBM of the first shell 43. That is, an ionization potential of the first core 42 is preferably lower than the ionization potential of the first shell 43. Thanks to such a feature, the holes are likely to be confined in the first cores 42, making it possible to increase a chance of recombination of the electrons and the holes in the first quantum dots 41. The first core preferably contains at least one selected from CdSe, ZnSe, InP, InGaP, AgInS₂, InN, InGaN, CuInS, CuInGaS, and ZnCuInS.

The first shell 43 preferably contains at least S or Se. Moreover, the first shell 43 preferably contains at least one selected from CdS, CdSe, ZnS, ZnSe, CdZnSe, CdZnS, and GaS.

Moreover, as to the first quantum dot 41, examples of preferable combinations of the first core 42 and the first shell 43 include.
(A1) a combination of at least one selected from CdSe and ZnSe, and at least one selected from CdS, ZnSe, and ZnS;
(A2) a combination of ZnSe and ZnS;
(A3) a combination of at least one selected from InP and InGaP, and at least one selected from GaP, ZnSe, and ZnS;
(A4) a combination of AgInS₂, and at least one selected from ZnS, GaS, and GaP;
(A5) a combination of at least one selected from InN and InGaN, and ZnS and; and
(A6) a combination of at least one selected from CuInS, CuInGaS, and ZnCuInS, and at least one selected from ZnS and ZnSe.

The second shell 46 preferably contains at least Te. Moreover, the second shell 46 more preferably contains, for example, at least one selected from AgInTe₂, CdTe, CdSTe, CdSeTe, ZnTe, ZnSTe, and ZnSeTe.

A VBM of the second core 46 is preferably lower than the VBM of the second shell 47. That is, an ionization potential of the second core 46 is preferably lower than the ionization potential of the second shell 47. Thanks to such features, if the VBM of the second core 46 is higher than, or equal to, the VBM of the second shell 47, the chance of recombination of the electrons and the holes in the second quantum dot 45 decreases, thereby reducing light to be emitted from the second core 46. In such a case, the light to be emitted from the light-emitting layer 4 depends on a wavelength of light to be emitted from the first quantum dots. Hence, the light-emitting element 100 can readily control the wavelength of light to be emitted. Moreover, the electrons and the holes are likely to be confined in the first quantum dots 41 than in the second quantum dots 45. Such a feature can increase a chance of recombination of the electrons and the holes in the first quantum dots 41 in the light-emitting layer 4. Furthermore, the second shells can further lower a barrier against the holes, thereby making it possible to further improve the carrier balance.

The second core 46 preferably contains at least one selected from, for example, CdSe, CdZnSe, ZnSe, InP, InGaP, AgInS₂. InN, InGaN, CuInS, CuInGaS, and ZnCuInS.

Moreover, as to the second quantum dot 45, examples of preferable combinations of the second core 46 and the second shell 47 include:
(B1) a combination of at least one selected from CdSe and ZnSe, and at least one selected from CdTe, CdSTe, CdSeTe, ZnTe, ZnSTe, and ZnSeTe;
(B2) a combination of ZnSe and ZnTe;
(B3) a combination of InP, and at least one selected from ZnTe, AlAs, and GaSb;
(B4) a combination of AgInSz, and at least one selected from AgInSe₂ and AgInTe₂;
(B5) a combination of at least one selected from InN and InGaN, and ZnSeTe; and
(B6) a combination of at least one selected from CuInS, CuInGaS, and ZnCuInS, and at least one selected from ZnTe and ZnSeTe:

Examples of preferable combinations of the first quantum dots 41 and the second quantum dots 45 include: a combination of (A1) and (B1); a combination of (A2) and (B2); a combination of (A3) and (B4); a combination of (A4) and (B4); a combination of (A5) and (B5); and a combination of (A6) and (B6).

Note that the combination of the first shell and the second shell may be determined in any given manner as long as a relationship “the CBM of the first shell is lower than the CMB of the second shell, and the VBM of the first shell is lower than the VBM of the second shell” is satisfied. The materials of the first shell and the second shell shall not be limited to the above materials. For example, the first shell and the second shell may respectively contain: CdS and ZnSe; CdS and AlSb; CdS and GaP; CdSe and AlAs; CdSe and AlSb; CdSe and ZnTe; CdSe and CdTe; ZnSe and AlSb; ZnSe and ZnTe: GaP and ZnTe; CdTe and AlSb: or CdTe and ZnTe. Note that the materials of the first shell and the second shall not be limited to these materials. That is, the first shell contains at least S or Se and the second shell contains Te. Such a feature makes it possible to readily select materials to satisfy the relationship “the CBM of the first shell is lower than the CMB of the second shell, and the VBM of the first shell is lower than the VBM of the second shell”.

Moreover, for example, a particle size of the second core 46 may be smaller than a particle size of the first core 42, so that the CBM of the second core 46 may be higher than the CBM of the first core 42; that is, the electron affinity of the second core 46 may be lower than the electron affinity of the first core 42. In such a case, more electrons are blocked compared with a case where the first quantum dots 41 alone are used for the light-emitting layer 4. Hence, the electron transport layer 5 or the cathode 6 can be made of a material that excels in transportation or injection of the electrons. Hence the materials can be selected more freely. In such a case, for example, the first core 42 and the second core 46 are preferably made of the same material.

Here, if the cores are made of ZnSe, a particle size of the cores corresponds to a core diameter (an assumed core diameter) of [6.1/{(1240/λp)−2.7}]\hat{ }(1/2) calculated using effective mass approximation with respect to ZnSe where a PL peak wavelength of a quantum dot is Xp (nm). Moreover, even if the first core 42 and the second core 46 are made of different materials, the core diameter (the assumed core diameter) can be calculated from the PL peak wavelength using a similar approximate calculation. This assumed core diameter can be interpreted as the core diameter.

Furthermore, for example, the first core 42 and the second core 46 may be made of the same material, and a particle size of the second core 46 may approximately be equal to a particle size of the first core 42. In such a case, for example, common cores are used for the first core 42 and the second core 46. Such a feature can save time and effort required for the production of the first quantum dots 41 and the second quantum dots 45.

Note that the first quantum dots 41 and the second quantum dots 45 may have ligands adsorbed (bonded) onto the surface of the quantum dots. In other words, the ligands are bonded to the exterior of the first shells 43 and the second shells 47. These ligands reduce deep-level defects on the surface of the first quantum dots 41 and the second quantum dots 45, thereby making it possible to prevent the holes from being trapped in the deep-level defects during transportation of the holes. The ligands can be selected appropriately from materials typically used in this field.

Moreover, if the VBM of the second core 46 is higher than, or equal to, the VBM of the second shell 47, a bandgap of the first core 42 is preferably approximately equal to a bandgap of the second core 46. That is, if the ionization potential of the second core 46 is lower than, or equal to, the ionization potential of the second shell 47, the bandgap of the first core 42 is preferably approximately equal to the bandgap of the second core 46. Alternatively, if the VBM of the second core 46 is lower than the VBM of the second shell 47, the bandgap of the first core 42 is preferably approximately equal to the difference between the CBM of the second core 46 and the VBM of the second shell 47. That is, if the ionization potential of the second core 46 is higher than the ionization potential of the second shell 47, a difference is preferably the same between the electron affinity of the second core 46 and the electron affinity of the second shell 47. That is, at least one wavelength in a wavelength range of light emitted from the first quantum dots 41 and at least one wavelength in a wavelength range of light emitted from the second quantum dots 45 may overlap with each other. Hence, the wavelengths of light emitted from the first quantum dots 41 and the second quantum dots 45 can match. Such a feature makes it possible to decrease a reduction in chromatic purity when the light-emitting element 100 emits light even when the second quantum dots 45 emit light. Note that, for example, if the VBM of the second core 46 is lower than the VBM of the second shell 47, a particle size of the second core 46 is smaller than a particle size of the first core 43, so that the bandgap of the first core 42 can readily be approximated to the difference between the CBM of the second core 46 and the VBM of the second shell 47.

Note that the first quantum dots 41 and the second quantum dots 45 in the light-emitting layer 4 can be identified, for example, as follows: The produced light-emitting element 100, including the light-emitting layer 4, is sectioned in a direction substantially perpendicular to the direction in which the layers of the light-emitting element 100 are stacked. Then, the TEM-EELS: that is, a combination of the transmission electron microscopy (TEM) and the electron energy-loss spectroscopy (EELS), is used to identify the first quantum dots 41 and the second quantum dots 45. Note that the sectioning means that the thickness of the light-emitting element 100 is reduced to 0.1 to 0.2 μm. More specifically, for example, the vicinity of the outer periphery portions of the quantum dots is analyzed so that a composition of the shells is determined; whereas, the vicinity of the center portions of the quantum dots is analyzed and elements (e.g., Te and S) unique to the shells are excluded so that a composition of the cores is determined. Thus, the composition of the quantum dots can be determined. For example, if the quantum dots included in a width of at least 0.2 μm are analyzed by the TEM-EELS and only the second quantum dots are detected, the quantum dots are understood “to consist only of the second quantum dots”.

Moreover, in the light-emitting element 100, a substrate (not shown) may be provided to a face of the anode 1 across from another face of the anode 1 provided with the hole injection layer 2, or to a face of the cathode 6 across from another face of the cathode 6 provided with the electron transport layer 5. The substrate is made of, for example, such a material as glass, and serves as a support body to support the layers. The substrate may be, for example, an array substrate including thin-film transistors (TFTs).

As to the light-emitting element of this embodiment, the light-emitting layer 4 contains the first quantum dots 41 and the second quantum dots 45. Such a feature can improve the carrier balance without impairing transportation of the holes in the light-emitting layer 4, so that the light-emitting element can improve light emission efficiency such as, for example, luminance and external quantum efficiency (EQE).

### Second Embodiment

This embodiment describes a difference from the first embodiment. For convenience in description, like reference signs designate identical constituent features between this embodiment and the first embodiment. These constituent features will not be elaborated upon.

The light-emitting element 100 of this embodiment is different as to the light-emitting layer 4 from that of the first embodiment. In the light-emitting layer 4 of this embodiment, a density of the second quantum dots 45 is higher toward the anode 1 than toward the cathode 6. In other words, the second quantum dots 45 are unevenly distributed toward the anode 1, and the first quantum dots 41 are unevenly distributed toward the cathode 6.

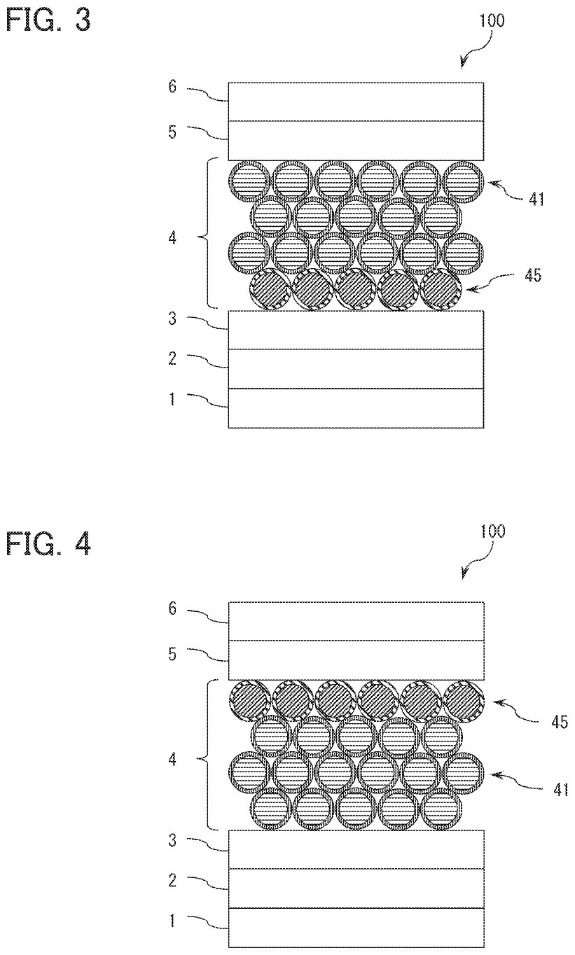

FIG. 3 is a schematic view of an exemplary multilayer structure of the light-emitting element 100 according to this embodiment.

The light-emitting layer 4 of this embodiment includes, as illustrated in, for example, FIG. 3, a layer made of the second quantum dots 45 and provided toward the anode 1 and a layer made of the first quantum dots 41 and provided toward the cathode 6. As can be seen, the light-emitting layer 4 includes: the second quantum dots 45 unevenly distributed toward the anode 1; and the first quantum dots 41 unevenly distributed toward the cathode 6. In successfully forming the light-emitting layer 4, for example, the layer of the second quantum dots 45 is formed on the hole transport layer 3, and, after that, the layer of the first quantum dots 41 is formed.

Moreover, in the light-emitting layer 4, the second quantum dots 45 may be gradationally arranged so that, for example, the density of the second quantum dots 45 may be higher toward the anode 1 and gradually lower toward the cathode 6. Furthermore, in the light-emitting layer 4, the first quantum dots 41 may be gradationally arranged so that, for example, the density of the first quantum dots 41 may be higher toward the cathode 6 and gradually lower toward the anode 1. Hence, the light-emitting layer 4, which includes the second quantum dots and the first quantum dots 41 gradationally arranged, can be formed, for example, as follows: A plurality of coating liquids are prepared such that each of the coating liquids contains the second quantum dots 45 and the first quantum dots 41 in different concentration. On the hole transport layer 3, a layer is formed of a coating liquid containing the second quantum dots 45 in high concentration. Sequentially, layers are formed of coating liquids containing the second quantum dots 45 in gradually lower concentration. Such layers are stacked on top on another to form the light-emitting layer 4.

Moreover, in the light-emitting layer 4, the density of the first quantum dots 41 is preferably lower toward the anode 1 than toward the cathode 6.

Note that the distribution of the first quantum dots 41 and the second quantum dots in the light-emitting layer 4 can be calculated, for example, as follows: The light-emitting layer 4 of the light-emitting element 100 is divided at least in half in a thickness direction. In the light-emitting layer 4, the same number of quantum dots (e.g., at least ten quantum dots) in a region closest to the anode 1 and in a region closest to the cathode 6 are analyzed. The number of the detected first quantum dots 41 and second quantum dots 45 represents the density (ratio) of the first quantum dots 41 and the second quantum dots 45.

The light-emitting element 100 of this embodiment can achieve the same advantageous effects as those of the light-emitting element 100 of the first embodiment. In addition, the first quantum dots 41 in the light-emitting layer 4 are positioned away from the hole transport layer 3 and arranged in high density, thereby making it possible to reduce deactivation of excitons on the surface of the hole transport layer 3 and to improve light emission efficiency of the first quantum dots 41. Such a feature can further improve light emission efficiency and reliability of the light-emitting element 100. In particular, if the hole transport layer 3 is formed of an inorganic material, the excitons are highly likely to be deactivated by a dipole moment on the surface of the hole transport layer 3. Hence, the light-emitting element 100 can further improve light emission efficiency and reliability.

### Third Embodiment

This embodiment describes a difference from the first and second embodiments. For convenience in description, like reference signs designate identical constituent features between this embodiment and the first and second embodiments. These constituent features will not be elaborated upon.

The light-emitting element 100 of this embodiment is different as to the light-emitting layer 4 from the light-emitting layers 4 of the first and second embodiments. In the light-emitting layer 4 of this embodiment, a density of the first quantum dots 41 is higher toward the anode 1 than toward the cathode 6. In other words, the first quantum dots 41 are unevenly distributed toward the anode 1, and the second quantum dots 45 are unevenly distributed toward the cathode 6.

FIG. 4 is a schematic view of an exemplary multilayer structure of the light-emitting element 100 according to this embodiment.

The light-emitting layer 4 of this embodiment includes, as illustrated in, for example, FIG. 4, a layer made of the first quantum dots 41 and provided toward the anode 1 and a layer made of the second quantum dots 45 and provided toward the cathode 6. As can be seen, the light-emitting layer 4 includes: the first quantum dots 41 unevenly distributed toward the anode 1; and the second quantum dots 45 unevenly distributed toward the cathode 6. In successfully forming the light-emitting layer 4, for example, the layer of the first quantum dots 41 is formed on the hole transport layer 3, and, after that, the layer of the second quantum dots 45 is formed.

Moreover, in the light-emitting layer 4, the first quantum dots 41 may be gradationally arranged so that the density of the first quantum dots 41 may be higher toward the anode 1 and gradually lower toward the cathode 6. Furthermore, in the light-emitting layer 4, the second quantum dots 45 may be gradationally arranged so that the density of the second quantum dots may be higher toward the cathode 6 and gradually lower toward the anode 1. Hence, the light-emitting layer 4, which includes the first quantum dots 41 and the second quantum dots 45 gradationally arranged, can be formed, for example, as follows: A plurality of coating liquids are prepared such that each of the coating liquids contains the first quantum dots 41 and the second quantum dots 45 in different concentration. On the hole transport layer 3, a layer is formed of a coating liquid containing the first quantum dots 41 in high concentration. Sequentially, layers are formed of coating liquids containing the first quantum dots 41 in gradually lower concentration. Such layers are stacked on top on another to form the light-emitting layer 4.

Moreover, in the light-emitting layer 4, the density of the second quantum dots 45 toward the anode 1 is preferably lower than the density of the first quantum dots 41 toward the cathode 6.

The light-emitting element 100 of this embodiment can achieve the same advantageous effects as those of the light-emitting element 100 of the first embodiment. In addition, the second quantum dots 45 toward the cathode 6 are arranged in high density, thereby making it possible to efficiently block the electrons to be transported from the electron transport layer 5 and improve the carrier balance in the light-emitting layer 4. Thanks to such a feature, the light-emitting element 100 can improve light emission efficiency such as, for example, luminance and EQE.

The present invention shall not be limited to the above embodiments, and may be replaced with configurations that are substantially the same as, that have the same advantageous effects as those of, and that achieve the same object as that of, the configurations described in the above embodiments.

1. A light-emitting element, comprising:
an anode;
a cathode provided across from the anode; and
a light-emitting layer provided between the anode and the cathode, and containing first quantum dots and second quantum dots, the first quantum dots each having a core-shell structure including a first core and a first shell provided on a surface of the first core, and the second quantum dots each having a core-shell structure including a second core and a second shell provided on a surface of the second core,
wherein a CBM of the first shell is lower than a CBM of the second shell, and
a VBM of the first shell is lower than a VBM of the second shell.

2. The light-emitting element according to claim 1,
wherein a VBM of the second core is lower than the VBM of the second shell.

3. The light-emitting element according to claim 1,
wherein a VBM of the first core is higher than the VBM of the first shell.

4. The light-emitting element according to claim 1,
wherein, in the light-emitting layer, a density of the second quantum dots is higher toward the anode than toward the cathode.

5. The light-emitting element according to claim 1,
wherein, in the light-emitting layer, a density of the first quantum dots is lower toward the anode than toward the cathode.

6. The light-emitting element according to claim 1,
wherein, in the light-emitting layer, a density of the second quantum dots is lower toward the anode than toward the cathode.

7. The light-emitting element according to claim 1,
wherein, in the light-emitting layer, a density of the first quantum dots is higher toward the anode than toward the cathode.

8. The light-emitting element according to claim 1,
wherein the light-emitting layer is composed only of the first quantum dots and the second quantum dots.

9. The light-emitting element according to claim 1,
wherein the first core and the second core are made of a same material, and a particle size of the second core is smaller than a particle size of the first core.

10. The light-emitting element according to claim 1,
wherein the first core and the second core are made of a same material, and a particle size of the second core is equal to a particle size of the first core.

11-13. (canceled)

14. A light-emitting element, comprising:
an anode;
a cathode provided across from the anode; and
a light-emitting layer provided between the anode and the cathode, and containing first quantum dots and second quantum dots, the first quantum dots each having a core-shell structure including a first core and a first shell provided on a surface of the first core, and the second quantum dots each having a core-shell structure including a second core and a second shell provided on a surface of the second core,
wherein the first shell contains at least S or Se, and
the second shell contains Te.

15-18. (canceled)

19. The light-emitting element according to claim 14,
wherein, in the light-emitting layer, a density of the second quantum dots is higher toward the anode than toward the cathode.

20. The light-emitting element according to claim 14,
wherein, in the light-emitting layer, a density of the first quantum dots is lower toward the anode than toward the cathode.

21. The light-emitting element according to claim 14,
wherein, in the light-emitting layer, a density of the second quantum dots is lower toward the anode than toward the cathode.

22. The light-emitting element according to claim 14,
wherein, in the light-emitting layer, a density of the first quantum dots is higher toward the anode than toward the cathode.

23. The light-emitting element according to claim 14,
wherein the light-emitting layer is composed only of the first quantum dots and the second quantum dots.

24-26. (canceled)

27. The light-emitting element according to claim 14,
wherein the first core and the second core are made of a same material, and a particle size of the second core is smaller than a particle size of the first core.

28. The light-emitting element according to claim 14,
wherein the first core and the second core are made of a same material, and a particle size of the second core is equal to a particle size of the first core.

29. The light-emitting element according to claim 14,
wherein at least the second quantum dots have ligands bonded to an exterior of the second shell.

30. The light-emitting element according to claim 14, further comprising
a hole transport layer provided between the anode and the light-emitting layer, the hole transport layer being made of an inorganic material.

31. (canceled)
